(19) United States
(12) Patent Application Publication
(10) Pub. No.: US 2024/0321760 A1
(43) Pub. Date: Sep. 26, 2024

(54) INTERPOSER WITH LINES HAVING PORTIONS SEPARATED BY BARRIER LAYERS

(71) Applicant: Microchip Technology Incorporated, Chandler, AZ (US)

(72) Inventors: Steve Nagel, Chandler, AZ (US); Bomy Chen, Newark, CA (US)

(73) Assignee: Microchip Technology Incorporated, Chandler, AZ (US)

(21) Appl. No.: 18/369,310

(22) Filed: Sep. 18, 2023

Related U.S. Application Data
(60) Provisional application No. 63/453,263, filed on Mar. 20, 2023.

(51) Int. Cl. H01L 23/538; H01L 21/48; H01L 25/065

(52) U.S. Cl. CPC H01L 23/5386; H01L 21/4857; H01L 23/5383; H01L 25/0655

(57) ABSTRACT

Interposers and methods for making interposers having a substrate having a surface defining a plane; a first portion of a metal line directly or indirectly supported by the substrate; a barrier layer on the first portion of the metal line; a second portion of the metal line on the first barrier layer, wherein the second portion is opposite the first portion across the barrier layer. The method includes etching a line pattern in a first portion of a metal layer through a first photoresist layer to form a first portion of a metal line, depositing a barrier layer on the first portion of the metal line, and etching a line pattern in a second portion of the metal layer through a second photoresist layer to form a second portion of a metal line wherein the second portion is opposite the first portion across the barrier layer.

### PRIORITY

This application claims priority to U.S. Provisional Patent Application No. 63/453,263, filed Mar. 20, 2023, the contents of which are hereby incorporated in their entirety.

### TECHNICAL FIELD

The present disclosure relates to interposers, in particular, interposers with metal lines connecting dies wherein the metal lines have portions separated by barrier layers.

### BACKGROUND

Interposers and similar heterogeneous integration solutions provide feature rich, highly integrated products. Interposers may utilize aluminum or copper lines and low k dielectrics. In particular, interposers may have metal lines for connecting the dies, wherein each metal line has a rectangular-shaped cross-section in a plane perpendicular to the interposer substrate. Copper line interposers have been widely used in the semiconductor industry and efficiently conduct alternating current, but they tend to be more expensive to produce. Aluminum line interposers are cheaper to produce than copper line interposers. However, aluminum line interposers have been used in the semiconductor industry much less than copper line interposers because they do not conduct alternating current (AC) as efficiently. Aluminum line interposers are typically used where high frequency alternating current performance is not a design criteria.

Etching is a manufacturing technique that removes material such as dielectrics, polymers, and metals. Wet etching uses a liquid solution (etchant in liquid phase) to remove material on a part-wide scale controlled by a mask. Masks are hardened material that resist the etchant so that material between channels in the mask may be removed while material covered by the mask is not removed. The depth of a wet etch may be controlled by the etch duration and rate while the width of the channel can be controlled by the size of the mask channel or opening. Wet etching techniques include: a dip method where the masked part is submerged in an etchant bath; and a spin/spray method where etchant is sprayed on the masked part when the part may or may not be rotating. Dry etching uses high kinetic energy beams containing high energy particles to remove or evaporate material from a part. The etchant is gas phase or ionized gasses in the plasma phase. The dry etch area may be controlled by a mask resistant to the kinetic energy beams. High aspect ratio geometric shapes may be dry etched in the material. Dry etching typically uses oxygen, fluorocarbons, chlorines, hydrogen, and bromine species in the plasma or gas phase. Dry etching techniques include: ion beam etching using argon, reactive ion etching (RIE), inductively coupled plasma RIE etching (ICP-RIE); and plasma etching capable of creating isotropic etch profiles. Generally, wet etching uses simpler equipment, is less complex, and is less expensive, compared to dry etching. Dry etching provides strong isotropic control and high precision, but it is not selective of materials and is more expensive.

Aluminum line interconnects have been made by subtractive etching of blanket aluminum layers defined by a patterned photoresist mask. Subtractive etching of aluminum interconnects is inexpensive. Scaling and performance demands have pushed a transition from aluminum to copper line interconnects. However, it is difficult to subtractively etch blanket copper layers using conventional etching techniques. Copper does not produce a volatile by-product during etching. In particular, chlorine gas forms a chloride that does not evaporate, but sticks to the surface and prevents underlying copper from etching. Thus, copper interconnects have been made by a Damascene process, which is an additive process, by: (1) depositing a dielectric layer, (2) wet etching the dielectric layer through a pattern photoresist mask, (3) depositing a barrier layer (Tantalum, Tantalum Nitride, or Titanium Nitride) over the dielectric layer, (4) depositing a thin seed layer of copper conformally over the barrier layer, (5) electroplating the seed layer with copper, and (6) planarize the copper using chemical mechanical planarization (CMP). While the Damascene process has good selectivity and resolution, it is an expensive process. There is a need for interposers that are cheaper to produce and have metal lines that efficiently conduct alternating current.

### SUMMARY OF THE INVENTION

Aspects provide interposers and methods for making interposers, wherein the interposers utilize metal lines having portions separated by dielectric layers, wherein the metal lines conduct alternating current at exterior surfaces and internal surfaces at the dielectric layers. The metal lines of the interposers may have non-rectangular cross-sectional shapes in planes perpendicular to interposer substrates. The interposers may also have air gaps adjacent to the metal lines.

An aspect provides a method for building an interposer, the method has providing a substrate having a surface defining a plane; depositing a first metal layer relative to the substrate; depositing a first photoresist layer on the first metal layer, making a line pattern in the first photoresist layer, etching the first metal layer through the patterned first photoresist layer to form a first portion of a metal line, and stripping the first photoresist layer; depositing a first insulation layer on the first portion of the metal line; depositing a barrier layer on the first insulation layer and the first portion of the metal line; depositing a second metal layer on the barrier layer; depositing a second photoresist layer on the second metal layer, making a line pattern in the second photoresist layer, etching the second metal layer through the patterned second photoresist layer to form a second portion of the metal line wherein the second portion is opposite the first portion across the barrier layer, and stripping the second photoresist layer.

According to an aspect, there is provided a device having a substrate having a surface defining a plane; a first portion of a metal line directly or indirectly supported by the substrate; a barrier layer on the first portion of the metal line; a second portion of the metal line on the first barrier layer, wherein the second portion is opposite the first portion across the barrier layer.

An aspect provides a system comprising: a first die; a second die; and an interposer comprising: a substrate having a surface defining a plane; a first portion of a metal line directly or indirectly supported by the substrate; a barrier layer on the first portion of the metal line; a second portion of the metal line on the first barrier layer, wherein the second portion is opposite the first portion across the barrier layer, a first die pad in electrical communication with the metal line, and a second die pad in electrical communication with the metal line, wherein the first die is in electrical communication with the first die pad and the second die is in electrical communication with the second die pad.

### BRIEF DESCRIPTION OF THE DRAWINGS

The figures illustrate examples of interposers having metal lines having portions separated by barrier layers so as to have interior surfaces at the barrier layers where alternating current may be conducted, wherein the metal lines may have non-rectangular cross-sections in a plane perpendicular to the interposer substrate. The interposers may also have air gaps adjacent to the metal lines.

FIG. 1 shows an interposer with metal lines through a bridge area connecting first and second chip dies.

FIGS. 2A-2Q show cross-sectional, end views of the interposer of FIG. 1 taken at cross-section A-A, wherein the figures show a process for building an interposer with metal lines and an air gap.

FIGS. 3A-3L show cross-sectional, end views of the interposer of FIG. 1 taken at cross-section A-A, wherein the figures show a process for building an interposer with metal lines.

FIG. 4 shows a cross-sectional, end view of an interposer with a lower level of metal lines, a middle level of metal lines, and an upper level of metal lines, wherein the middle level of metal lines has first and second metal line portions separated by a barrier, and the middle level of metal lines has an air gap.

FIG. 5 shows a cross-sectional, end view of an interposer with a lower level of metal lines, a middle level of metal lines, and an upper level of metal lines.

FIG. 6 shows a cross-sectional, end view of an interposer with a lower level of metal lines, a middle level of metal lines, an upper level of metal lines, and a top level of metal lines.

FIG. 7A shows a cross-sectional, end view of aluminum metal lines and air gaps, wherein respective ones of the aluminum metal lines have a first portion and a second portion separated by a barrier layer and the portions have a generally trapezoidal shape.

FIG. 7B shows a cross-sectional, end view of a copper metal line having a prior art rectangular shape.

FIG. 8A shows a top view of an interposer with metal lines through a bridge area connecting first and second chip dies.

FIG. 8B shows a cross-sectional, side view taken at cross-section B-B of FIG. 8A of a metal line having a first portion and a second portion separated by a barrier layer.

FIGS. 8C-8P show cross-sectional, end views of the interposer of FIG. 8A taken at cross-section A-A, wherein the figures show a process for building an interposer with metal lines and air gaps.

FIG. 9 is a flow chart for a method of producing an interposer with metal lines having first and second portions separated by a barrier layer.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect, there is provided interposers and methods for building interposers with metal lines having portions separated by barrier layers so as to have interior surfaces at the barrier layers where alternating current may be conducted, wherein the metal lines may have cross-sections perpendicular to the interposer substrate that are non-rectangular shapes. Further, performance may be increased by making air gaps adjacent to the metal lines.

Aspects provide interposers, and method for inexpensively making interposers, with efficient high frequency alternating current (AC) performance. The interposers may have efficient high frequency alternating current (AC) performance due to “skin effect” or tendency of an AC current to be distributed within a conductor such that the current density is largest near the surface. Aspects provide interposers with metal lines that have cross-sections perpendicular to the interposer substrate with shapes that are non-rectangular, so as to provide a surface area larger than a cross-section with a rectangular shape for a metal wire of the same thickness. Further, aspects provide interposers with air gaps adjacent metal lines to reduce RC delay, wherein RC delay is the delay of the electrical signal produced by the combination of resistance and capacitance of that part of the metal line. Another aspect provides aluminum metal lines.

Plasma etching aluminum tends to result in trapezoidal shaped features. Stacking two plasma etched aluminum line portions on top of each other, separated by a barrier layer in the metal line or transmission line runs, results in a significantly increased surface area versus the rectangular shaped copper line commonly used. Air gaps may be formed adjacent to the metal lines via a multistep process utilizing a hardmask, sub gaps in the hardmask, and a wet/dry etch combination through the hardmask. A hardmask may be formed by two blanket depositions that are done back to back-first depositing nitride and then depositing oxide. These depositions may be patterned and etched with the same photoresist layer. After a dry etch of the metal line (e.g., aluminum), a wet etch removes the insulation layer (e.g., oxide) remaining between the metal in the air gap regions. The oxide of the hardmask may be removed during this step but the nitride may remain and keep the sub gaps defined. If the absence of nitride, the sub gaps may be gone after the wet etch and the subsequent oxide deposition may fill the air gap space between the metal lines. The sub gaps may be small enough so that the non-conformal oxide deposition closes the sub gaps during deposition without filling the underlying air gap space between the metal lines. The oxide at the top of the hardmask may preclude etching the nitride of the hardmask away while etching the barrier (e.g., a dielectric such as a nitride) between portions of the metal layer (e.g., aluminum). Air gaps may be formed via this process in areas where the metal lines are to transmit or conduct high frequency alternating current.

The use of a non-conformal oxide deposition seals air gaps between the lines. The addition of Sn directly on top of the top aluminum line prevents Al₂O₃ formation and allows for direct connection of chips with solder balls to interposer pads.

Aluminum interposers, i.e., interposers with aluminum lines, may be less expensive than copper interposers, i.e., interposers with copper lines. Aluminum interposers may be compatible with legacy semiconductor fabrication capabilities and utilize commonly available tool sets. Aluminum interposers may have significantly increased metal line transmission surface area as compared with copper interposers. An air gap between metal lines may provide for a dielectric constant near one (1), which may provide improved resistive-capacitive delay. A tin (Sn) layer on top of aluminum may allow for direct soldering of a balled chip to the interposer.

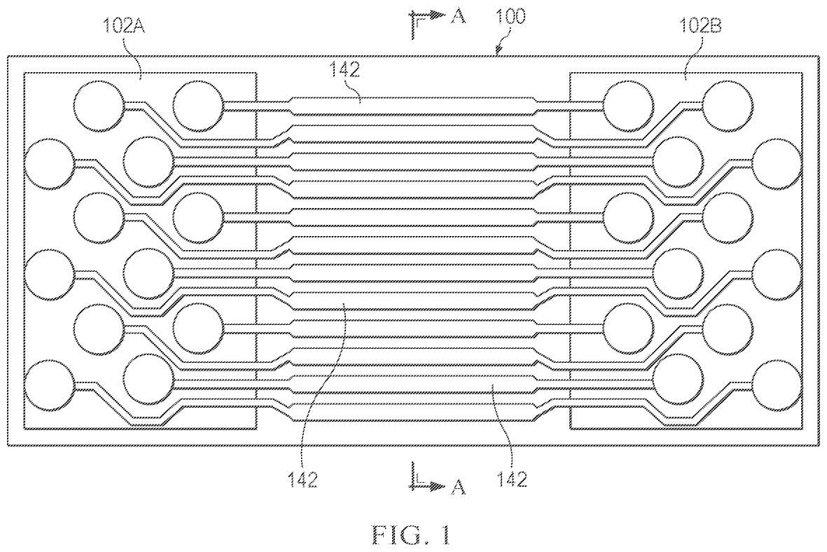

FIG. 1 shows a top view of a first chip die 102A and a second chip die 102B on an interposer 100, wherein the first and second chip dies 102A, 102B are connected by metal lines 142 of the interposer 100.

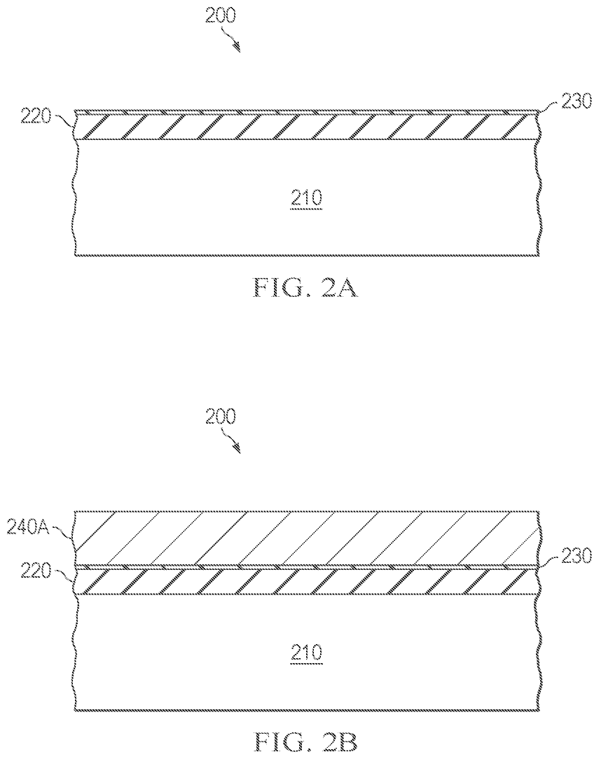

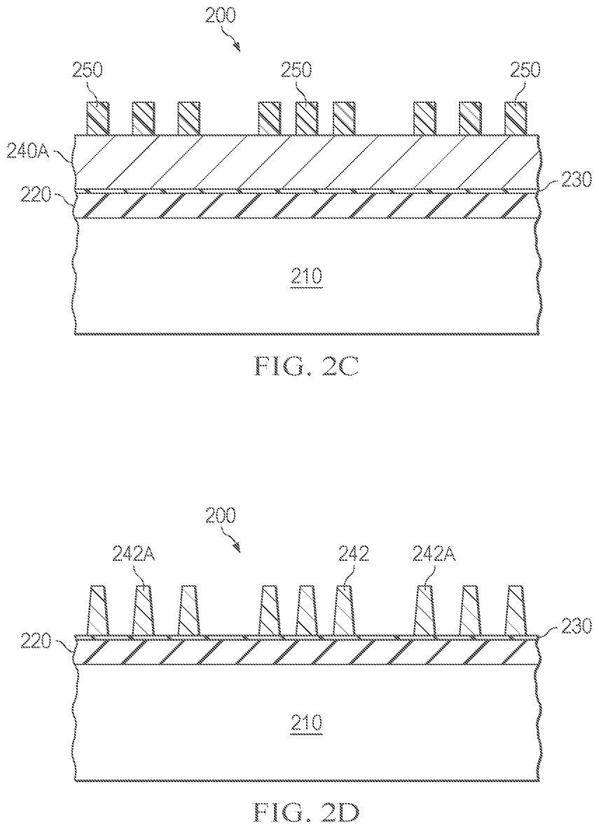

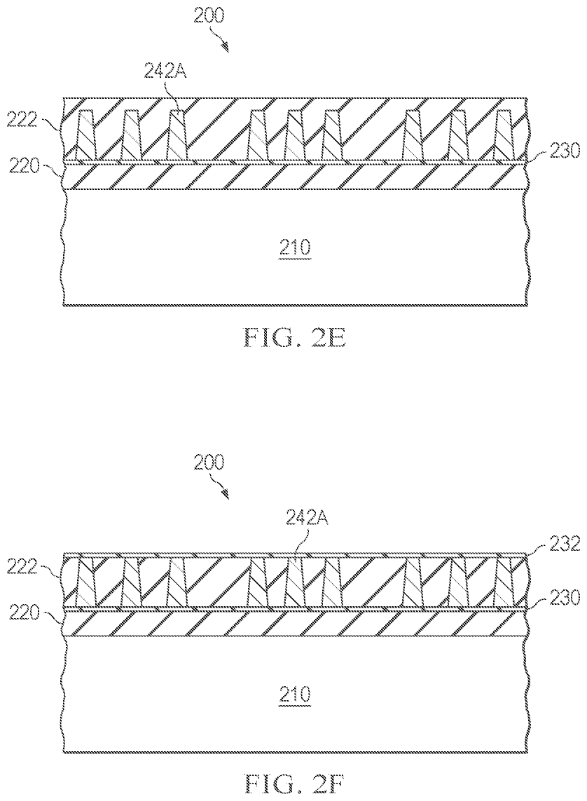

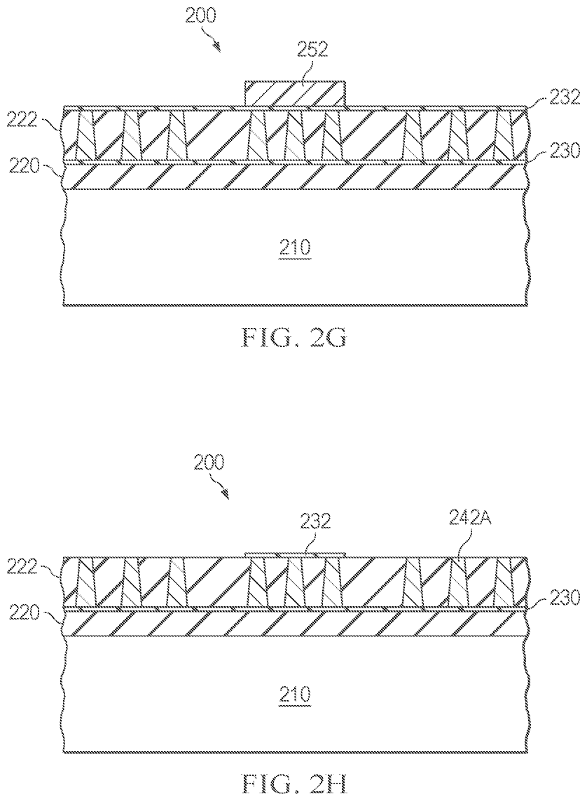

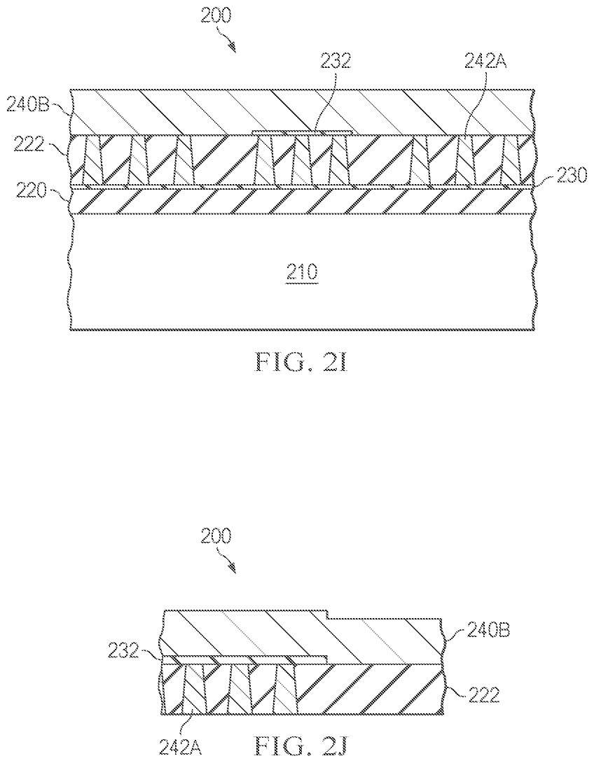

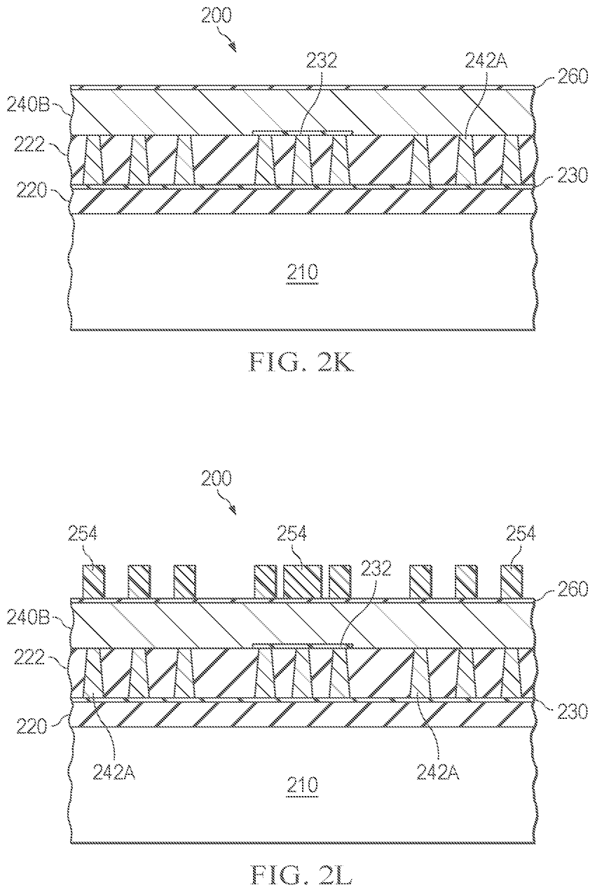

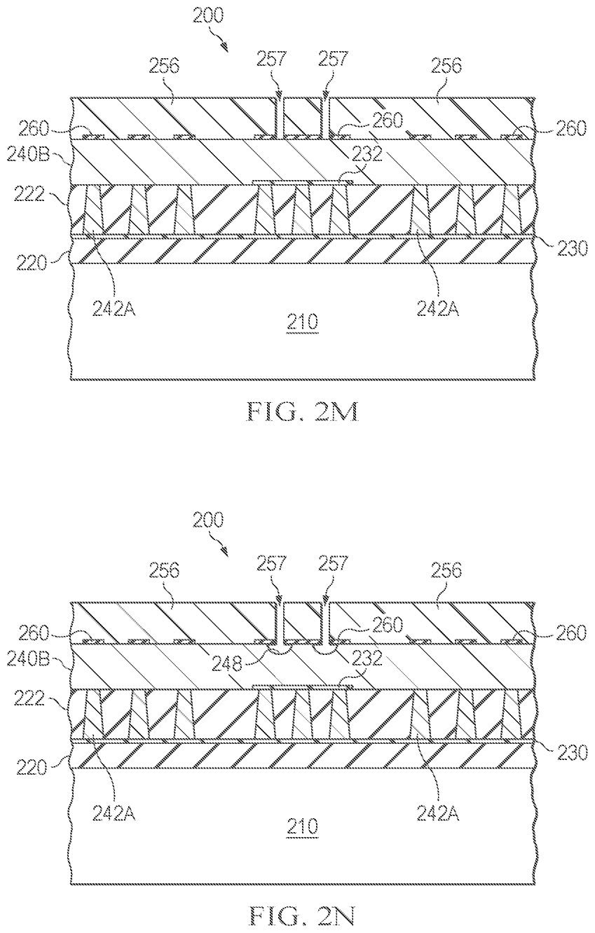

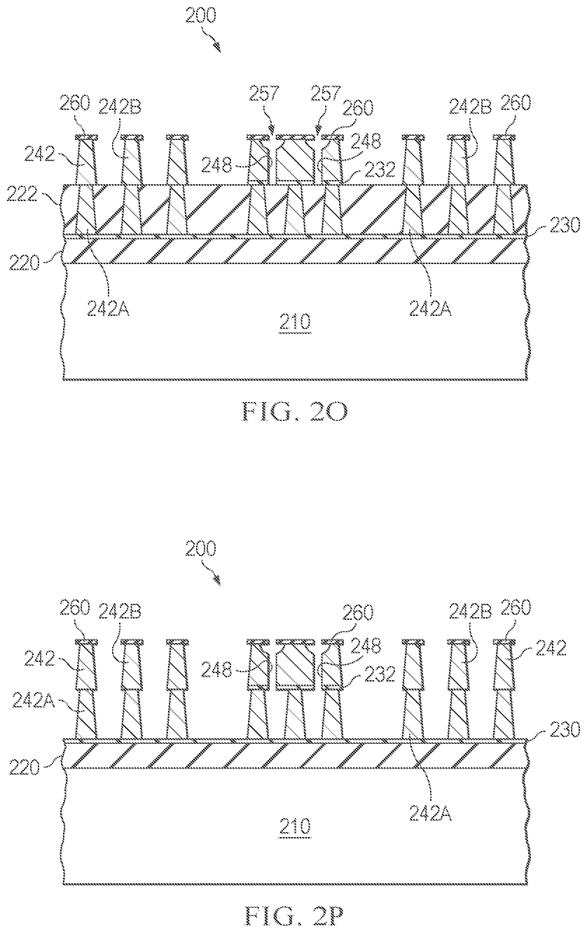

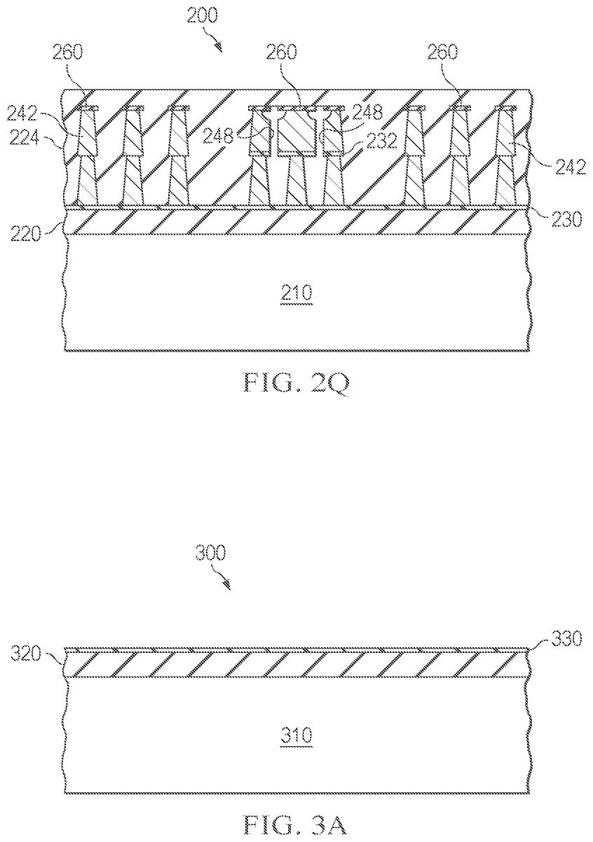

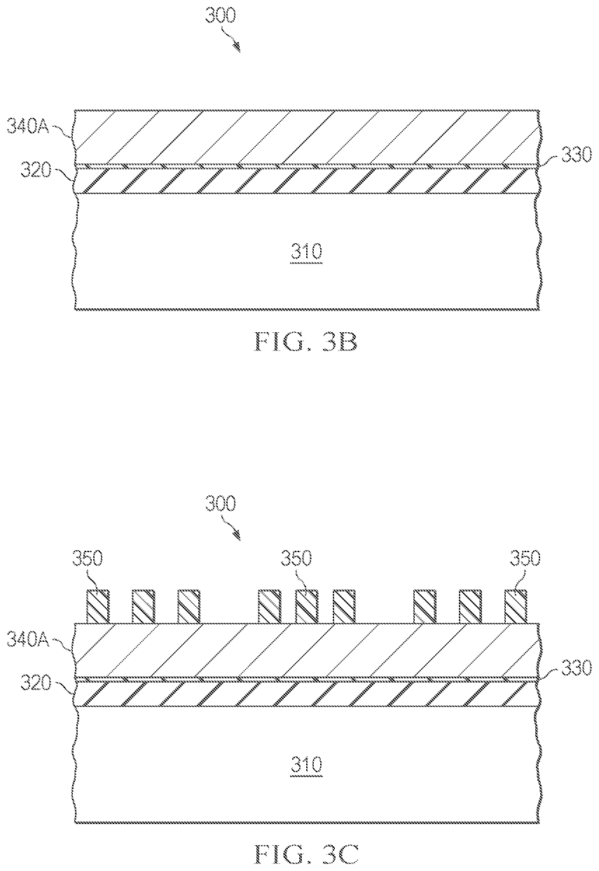

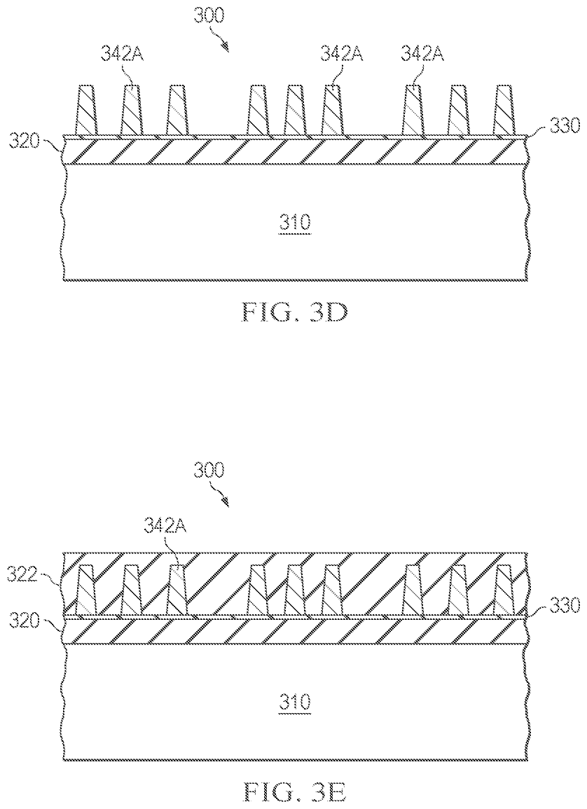

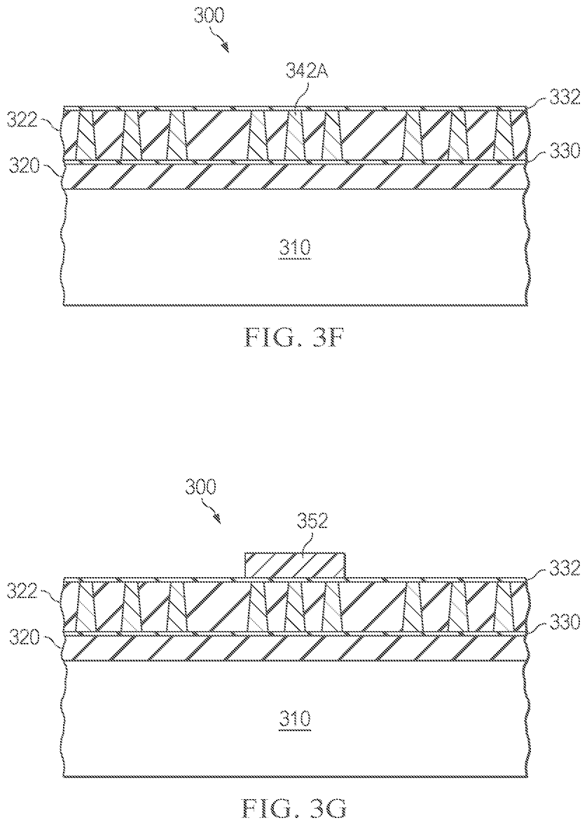

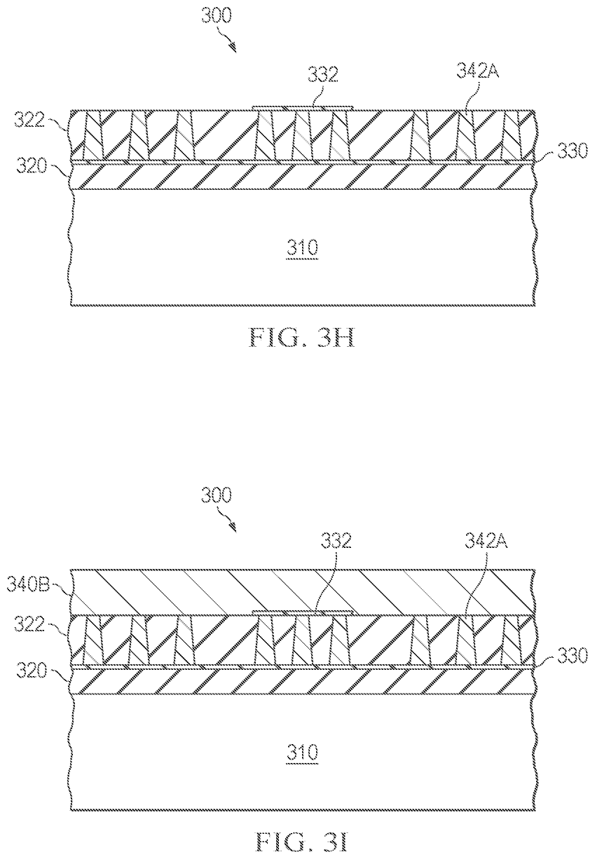

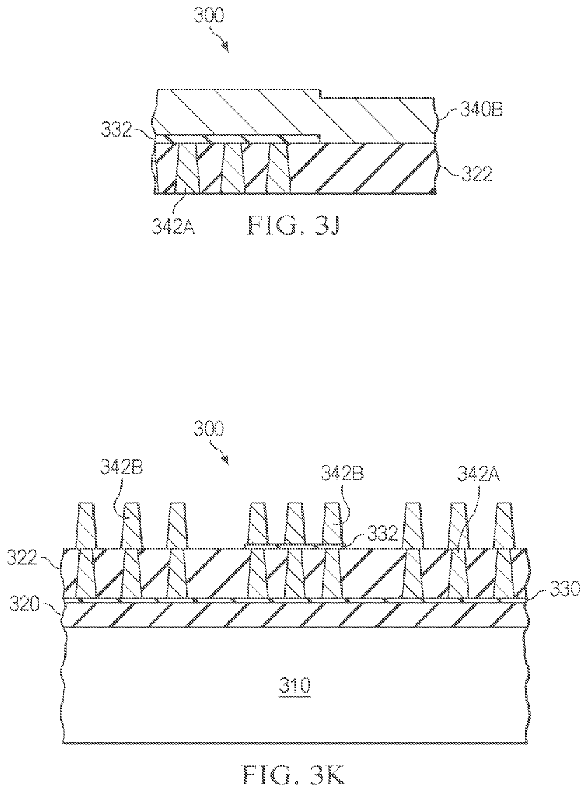

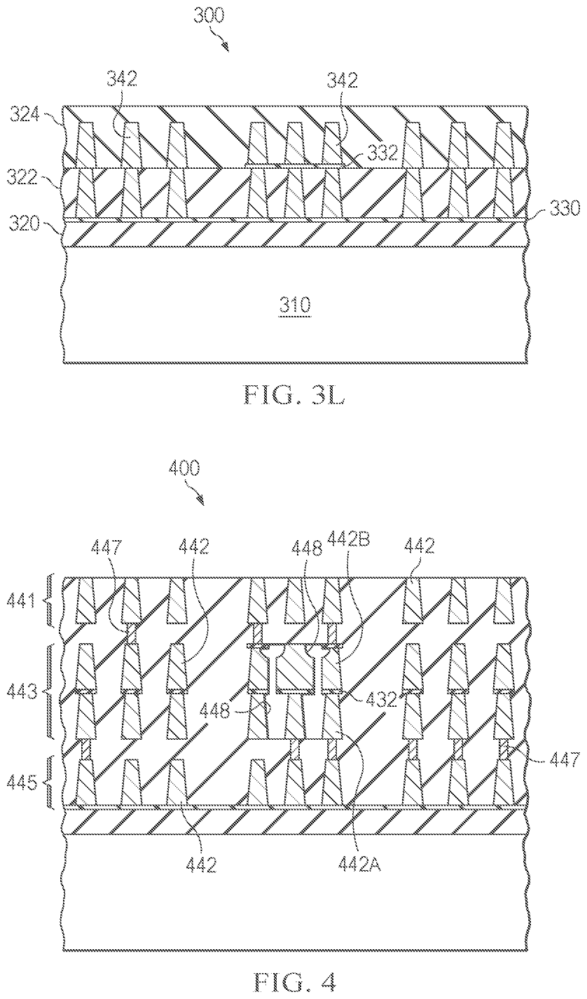

Two aspects are described, which both use a barrier layer, such as a dielectric, with the metal lines having increased skin area to reduce its effective resistance for alternating current. A barrier layer between two portions of a metal line enables the metal line to have interior surfaces at the barrier layer where alternating current may be conducted efficiently. A barrier layer may comprise a dielectric material, such as a nitride. To improve capacitance between adjacent metal lines, additional steps may be performed to create an air gap between the metal lines. FIGS. 2A-2Q show an air gap interposer. FIGS. 3A-3L show a non-air gap interposer. An air gap may be useful for signal transmission. No air gap may be useful for power or ground. An air gap interposer may improve both effective resistance and capacitance. A non-air gap interposer may improve effective resistance.

FIG. 2A shows a cross-sectional end view of an interposer 200 being built, which corresponds to the interposer 100 shown in FIG. 1, wherein the cross-section is at cross-section A-A. A substrate insulation layer 220, which may comprise an oxide such as silicon oxide (SiO₂), is deposited or grown on silicon substrate 210. A substrate barrier layer 230, which may comprise a nitride such as silicon nitride, is deposited on the substrate insulation layer 220. FIG. 3A shows a cross-sectional end view of an interposer 300 being built. A substrate insulation layer 320, which may comprise an oxide such as SiO₂, is deposited or grown on silicon substrate 310. Interposer 300 similarly has a substrate barrier layer 330, which may comprise a nitride such as silicon nitride, deposited on the substrate insulation layer 320.

FIG. 2B shows a cross-sectional end view of the interposer 200 being built as shown in FIG. 2A. A first portion of metal layer 240A is deposited on the substrate barrier layer 230. In this aspect, the first portion of metal layer 240A may be comprised of aluminum or copper, or another metal, without limitation. Alternatively, the first portion of metal layer 240A may be deposited directly on the silicon substrate 210 so as to be supported directly by the silicon substrate 210. As shown in FIG. 2B, the first portion of the metal layer 240A is indirectly supported by the silicon substrate 210 because the substrate insulation layer 220 and the substrate barrier layer 230 are between the silicon substrate 210 and the first portion of the metal layer 240A. FIG. 3B shows a cross-sectional end view of the interposer 300 being built as shown in FIG. 3A. A first portion of metal layer 340A is deposited on the substrate barrier layer 330. In this aspect, the first portion of metal layer 340A may be comprised of aluminum or copper, or another metal, without limitation. Alternatively, the first portion of metal layer 340A may be deposited directly on the silicon substrate 310 so as to be supported directly by the silicon substrate 310. As shown in FIG. 3B, the first portion of the metal layer 340A is indirectly supported by the silicon substrate 310 because the substrate insulation layer 320 and the substrate barrier layer 230 are between the silicon substrate 310 and the first portion of the metal layer 340A.

FIG. 2C shows a cross-sectional end view of the interposer 200 being built as shown in FIG. 2B. A first photoresist layer 250 is applied to the first portion of metal layer 240A and patterned to form channels through which metal lines may be formed (not yet formed) in the first portion of metal layer 240A. FIG. 3C shows a cross-sectional end view of the interposer 300 being built as shown in FIG. 3B. A first photoresist layer 350 is applied to the first portion of metal layer 340A and patterned to form channels through which metal lines may be formed (not yet formed) in the first portion of metal layer 340A.

FIG. 2D shows a cross-sectional end view of the interposer 200 being built as shown in FIG. 2C. The first portion of metal layer 240A is dry etched through the patterned first photoresist layer 250 to the substrate barrier layer 230 and the patterned first photoresist layer 250 (see FIG. 2C) is subsequently stripped to produce first portions of metal lines 242A. The first portion of metal layer 240A is thus dry etched to form first portions of the metal lines 242A having cross-sections perpendicular to the top surface plane of the silicon substrate 210 that are non-rectangular shapes. In particular, the cross-sections may be trapezoidal shaped. FIG. 3D shows a cross-sectional end view of the interposer 300 being built as shown in FIG. 3C. The first portion of metal layer 340A is dry etched through the patterned first photoresist layer 350 to the substrate barrier layer 330 and the patterned first photoresist layer 350 (see FIG. 3C) is subsequently stripped to produce first portions of metal lines 342A. The first portion of metal layer 340A is thus dry etched to form first portions of the metal lines 342A having cross-sections perpendicular to the top surface plane of the silicon substrate 310 that are non-rectangular shapes. In particular, the cross-sections may be trapezoidal shaped.

FIG. 2E shows a cross-sectional end view of the interposer 200 being built as shown in FIG. 2D. A first insulation layer 222, which may comprise SiO₂, is deposited or grown on substrate barrier layer 230 and the first portions of metal lines 242A. FIG. 3E shows a cross-sectional end view of the interposer 300 being built as shown in FIG. 3D. A first insulation layer 322, which may comprise SiO₂, is deposited or grown on substrate barrier layer 330 and the first portions of metal lines 342A.

FIG. 2F shows a cross-sectional end view of the interposer 200 being built as shown in FIG. 2E. The first insulation layer 222 and the first portions of metal lines 242A are planarized and a first barrier layer 232, which may comprise nitride, is deposited thereon. FIG. 3F shows a cross-sectional end view of the interposer 300 being built as shown in FIG. 3E. The first insulation layer 322 and the first portions of metal lines 342A are planarized and a first barrier layer 332, which may comprise nitride, is deposited thereon.

FIG. 2G shows a cross-sectional end view of the interposer 200 being built as shown in FIG. 2F. A barrier photoresist layer 252 is applied to the first barrier layer 232 and patterned to leave metal lines designed for increased resistance, capacitance (RC) or power. An air gap may be useful for signal transmission, and therefore the metal lines may be high-speed transmission metal lines. An air gap interposer may improve both effective resistance and capacitance. FIG. 3G shows a cross-sectional end view of the interposer 300 being built as shown in FIG. 3F. A barrier photoresist layer 352 is applied to the first barrier layer 332 and patterned to leave metal lines designed for increased resistance, capacitance (RC) or power. The lack of air gap may be useful for power or ground. A non-air gap interposer may improve effective resistance.

FIG. 2H shows a cross-sectional end view of the interposer 200 being built as shown in FIG. 2G. The first barrier layer 232 is wet etched through the patterned barrier photoresist layer 252 and the barrier photoresist layer 252 (see FIG. 2G) is subsequently stripped. FIG. 3H shows a cross-sectional end view of the interposer 300 being built as shown in FIG. 3G. The first barrier layer 332 is wet etched through the patterned barrier photoresist layer 352 and the barrier photoresist layer 352 (see FIG. 2G) is subsequently stripped.

FIG. 2I shows a cross-sectional end view of the interposer 200 being built as shown in FIG. 2H. A second portion of metal layer 240B, which may comprise aluminum, is deposited on the remaining portion of first barrier layer 232, the first insulation layer 222, and the first portions of metal lines 242A that are exposed. FIG. 3I shows a cross-sectional end view of the interposer 300 being built as shown in FIG. 3H. A second portion of metal layer 340B, which may comprise aluminum, is deposited on the remaining portion of first barrier layer 332, the first insulation layer 322, and the first portions of metal lines 342A that are exposed.

FIG. 2J shows an enlarged view of the remaining first barrier layer 232 of the interposer 200 shown in FIG. 2I. The first barrier layer 232, which may be a dielectric such as a nitride, forms a barrier between the first portions of the metal line 242A and the second portion of metal layer 240B. FIG. 3J shows an enlarged view of the remaining first barrier layer 332 of the interposer 300 shown in FIG. 3I. The first barrier layer 332, which may be a dielectric such as a nitride, forms a barrier between the first portions of the metal line 342A and the second portion of metal layer 340B.

As noted above, FIGS. 2A-2Q show an air gap interposer and FIGS. 3A-3L show a non-air gap interposer. Here the processes for making the different interposers diverge.

FIG. 2K shows a cross-sectional end view of the interposer 200 being built as shown in FIG. 2I. A hardmask 260 is deposited on the second portion of metal layer 240B. The hardmask 260 may be formed by two blanket depositions that are done back to back; first deposit a sub-layer of nitride and then deposit a sub-layer of oxide. These depositions may be patterned and etched with the same photoresist layer.

FIG. 2L shows a cross-sectional end view of the interposer 200 being built as shown in FIG. 2K. A second photoresist layer 254 is deposited on the hardmask 260 and patterned to correspond to the pattern of the first portions of metal lines 242A. The oxide and nitride sub-layers of the hardmask 260 are etched through the second photoresist layer 254 to the second portion of metal layer 240B and the second photoresist layer 254 is subsequently stripped. The etchant used to etch the oxide and nitride sublayers of the hardmask 260 is selective of the oxide and nitride and stops at the second portion of metal layer 240B. FIG. 2M shows a cross-sectional end view of the interposer 200 being built as shown in FIG. 2L. A third photoresist layer 256 is applied to the remaining hardmask 260 and the second portion of metal layer 240B. The third photoresist layer 256 is patterned to etch portions of the remaining hardmask 260 through which air gap areas may be subsequently formed. In particular, the third photoresist layer 256 is patterned to etch sub gaps 257 in the hardmask 260. The remaining hardmask 260 is etched through the patterned third photoresist layer 256 to remove remaining portions of the hardmask 260 to create sub gaps 257 where air gap areas are to be formed.

FIG. 2N shows a cross-sectional end view of the interposer 200 being built as shown in FIG. 2M. The second portion of metal layer 240B is wet etched to begin the formation of air gaps 248. In particular, a liquid etchant is flowed through the patterned third photoresist layer 256 and the etched sub gaps 257 in hardmask 260 to the second portion of metal layer 240B and portions of the second portion of metal layer 240B are etched away to begin the formation of air gaps 248. As indicated above, the second portion of metal layer 240B may be aluminum. The third photoresist layer 256 is stripped after the air gaps 248 have begun to be formed. Forming the air gaps 248 is a multistep process, wherein the second portion of the metal layer 240B is dry etched to the second insulating layer 222 and then the second insulating layer 222 in the area of the air gaps 248 is removed via a wet etch, as described more fully below.

FIG. 2O shows a cross-sectional end view of the interposer 200 being built as shown in FIG. 2N. The second portion of metal layer 240B (see FIG. 2N) is dry etched through the remaining hardmask 260 to the first insulation layer 222, whereby second portions of metal lines 242B are formed connected to first portions of metal lines 242A. For some of the metal lines 242, the second portion 242B is connected directly to the first portion 242A. For other metal lines 242, the second portion 242B is connected indirectly to the first portion 242A through the first barrier layer 232, as a result of patterned barrier photoresist layer 252, described above in relation to FIGS. 2G-2H. For metal lines 242 with a first barrier layer 232, the second portion of the metal line 242B is opposite the first portion of the metal line 242A across the first barrier layer 232, as shown in FIG. 2O. The second portion of metal layer 240B is dry etched to form second portions of the metal lines 242B having cross-sections perpendicular to the top surface plane of the silicon substrate 210 that are non-rectangular shapes. In particular, the cross-sections of the second portions of the metal lines 242B may be trapezoidal shaped. This dry etching through the remaining hardmask 260 also further forms the air gaps 248 by removing more material of the second portion of metal layer 240B (see FIG. 2N) to the first insulation layer 222.

FIG. 3K shows a cross-sectional end view of the interposer 300 being built as shown in FIG. 3I. A nitride and oxide hardmask (not shown) had been deposited on the second metal layer 344 (see FIG. 3I). A second photoresist layer had been deposited on the hardmask and patterned to correspond to the pattern of the first portions of metal lines 342A. The oxide and nitride of the hardmask were etched through the patterned third photoresist layer to the second metal layer 344 (see FIG. 3I) and the third photoresist layer was subsequently stripped. The etchant was selective of the oxide and nitride of the hardmask and stopped at the second metal layer 344. The second metal layer 344 has been dry etched through the hardmask to the first insulation layer 322, whereby metal line upper portions 342B were produced to be connected to metal line lower portions 342A. For some of the metal lines 342, the upper portion 342B is connected directly to the lower portion 342A. For other metal lines 342, the upper portion 342B is connected indirectly to the lower portion 342A through the first barrier layer 332 as a result of patterned barrier photoresist layer 352, described above in relation to FIGS. 3G-3H. For metal lines 342 with a first barrier layer 332, the second portion of the metal line 342B is opposite the first portion of the metal line 342A across the first barrier layer 332, as shown in FIG. 3K. The second metal layer 344 was dry etched to form second portions of the metal lines 342B having cross-sections perpendicular to the top surface plane of the silicon substrate 210 that are non-rectangular shapes. In particular, the cross-sections of the second portions of the metal lines 342B may be trapezoidal shaped.

FIG. 2P shows a cross-sectional end view of the interposer 200 being built as shown in FIG. 2O. A wet etch process is applied to remove the first insulation layer 222 (see FIG. 2O) from the substrate barrier layer 230 and the first portion of metal lines 242A and second portion of metal lines 242B. This wet etch process further extends the air gaps to the substrate barrier layer 230. After a dry etch of the second portion of the metal layer 204B (e.g., aluminum) (see FIG. 2O), a wet etch removes the insulation layer (e.g., oxide) remaining between the metal in the air gap regions (see FIG. 2P). The oxide of the hardmask may be removed during this step but the nitride may remain and keep the sub gaps 257 defined. If the nitride isn't there, the sub gaps may be gone after the wet etch and the subsequent oxide deposition may fill the air gap space between the metal lines. The sub gaps 257 may be small enough so that the non-conformal oxide deposition of the second insulation layer, described below, closes the sub gaps during deposition without filling the underlying air gap 248 space between the metal lines 242. The oxide at the top of the hardmask 260 may preclude etching the nitride of the hardmask 260 away while etching the first barrier layer 232 (e.g., a dielectric such as a nitride) between portions of the metal layer 240A and 240B (e.g., aluminum). Air gaps 248 may be formed via this air gap process in areas where the metal lines are to transmit or conduct high frequency alternating current.

FIG. 2Q shows a cross-sectional end view of the interposer 200 being built as shown in FIG. 2P. A second insulation layer 224, which may comprise SiO₂, is deposited or grown over the metal lines 242, the nitride layer 230, and the remaining hardmask 260. Because the size of etched holes in the remaining hardmask 260 at the air gaps 248 are too small to allow insulation material to pass therethrough, the second insulation layer 224 does not fill the air gaps 248. As shown in FIG. 2Q, the interposer 200 is fully built with metal lines 242 and air gaps 248 in a bridge region between the first and second chip dies 102A and 102B. See FIG. 1. Also, FIG. 3L shows a cross-sectional end view of the interposer 300 being built as shown in FIG. 3K. A second insulation layer 324, which may comprise SiO₂, is deposited or grown over the metal lines 342 and the first insulation layer 322. As shown in FIG. 3L, the interposer 300 is fully built with metal lines 342.

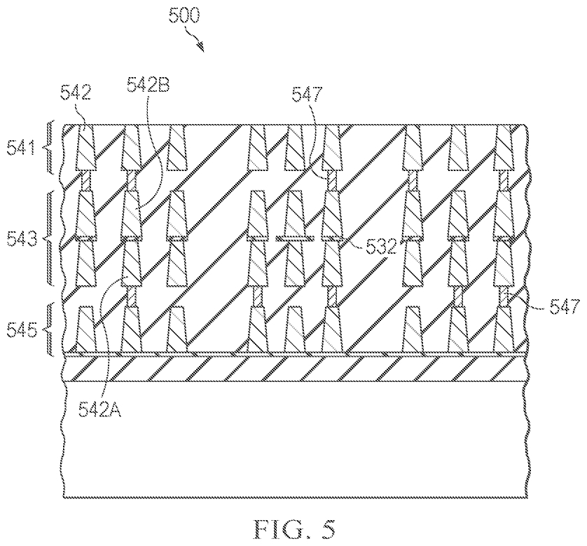

FIG. 4 shows a cross-sectional end view of an interposer 400 having a full stack of metal lines 442, wherein the cross-section is taken at cross-section A-A shown in FIG. 1. An upper level 441 of single stack metal lines 442 may be used for a positive supply voltage or ground. A middle level 443 may comprise metal lines 442 comprised of lower portions 442A and upper portions 442B separated by second barrier layer 432. The second barrier layer 432 may be a dielectric between portions of the metal lines 442, which may increase the skin effect. The dielectric may be a nitride. The metal lines 442 in the middle level 443 may be used for transmission. Vias 447 may provide connectivity between the upper level 441 and the middle level 443. Vias 447 may be formed by filling holes with aluminum, if large enough, or formed using a tungsten via process (e.g., deposit barrier layer, chemical vapor deposition (CVD) of tungsten, and chemical mechanical polishing (CMP) until flat. A lower level 445 may comprise a single stack of metal lines 442, which may also be used for a second supply voltage or ground. Vias 447 may provide connectivity between the lower level 445 and the middle level 443. The interposer 400 has air gaps 448 adjacent metal lines 442 in the middle level 443.

FIG. 5 shows a cross-sectional end view of an interposer 500 having a full stack of metal lines, wherein the cross-section is taken at cross-section A-A shown in FIG. 1. An upper level 541 of single stack metal lines 542 may be used for a supply voltage or ground. A middle level 543 may comprise metal lines 542 comprising lower portions 542A and upper portions 542B separated by second barrier layer 532. The second barrier layer 532 may be a dielectric between portions of the metal lines 542, which may increase the skin effect. The dielectric may be a nitride. The metal lines 542 in the middle level 543 may be used for transmission. Vias 547 may provide connectivity between the upper level 541 and the middle level 543. A lower level 545 may comprise a single stack of metal lines 542, which may also be used for a second supply voltage or ground. Vias 547 may provide connectivity between the lower level 545 and the middle level 543.

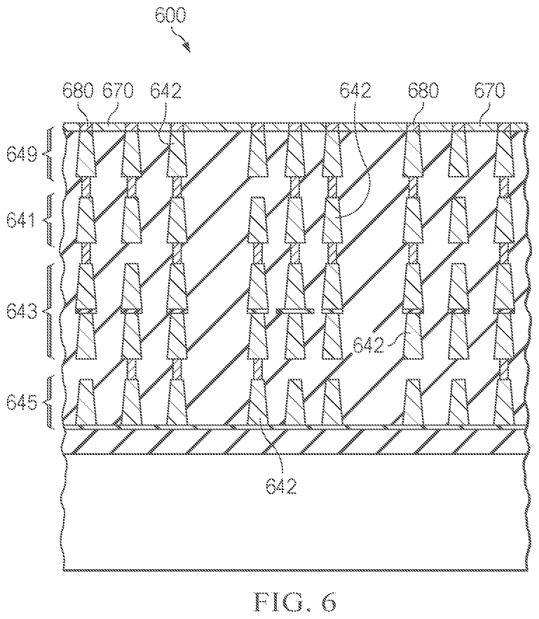

FIG. 6 shows a cross-sectional end view of an interposer 600 having a full stack of metal lines, wherein the cross-section is taken at cross-section A-A shown in FIG. 1. The interposer 600 has a top level 649 of single stack metal lines 642 above an upper level 641, a middle level 643, and a lower level 645. The interposer 600 may also have a top metal layer 670, wherein the top metal layer 670 may be tin (Sn) or nickel (Ni) with tin (Sn) thereon, the top metal layer 670 sputtered directly on the top level 649 of single stack metal lines 642. The metal lines 642 may be made of aluminum (Al). Pads 680 may be formed on the top surface of the interposer 600 at the single stack metal lines 642 to provide direct connectivity with chip dies (not shown). The pads 680 may be tungsten (W). This may allow the pads 680 to directly accept attachment of solder balls from a chip.

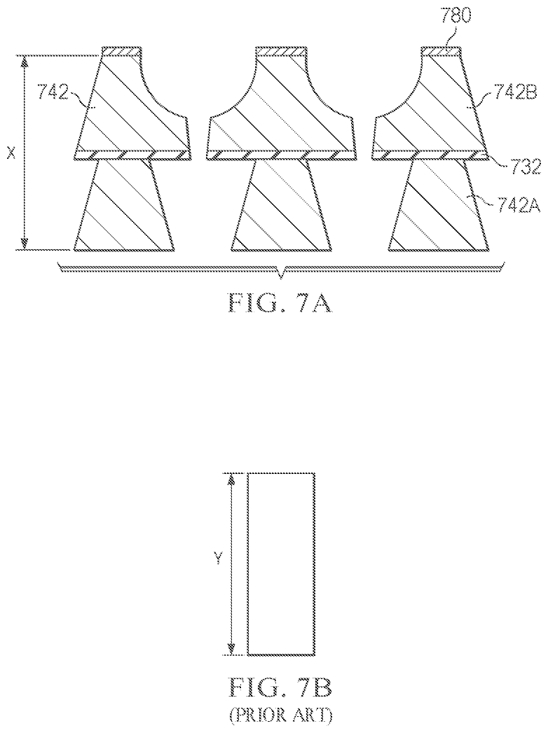

FIG. 7A shows a cross-sectional end view of metal lines of an interposer for connecting chips. The respective metal lines 742 have lower portions 742A and upper portions 742B separated by a barrier layer 732. The cross-section of a metal line 742 is non-rectangular, for example, a stack of generally trapezoidal shapes and is about X units (may be about 7 μm) thick in a vertical direction. Skin effect is the tendency of an alternating electric current (AC) to become distributed within a conductor such that the current density is largest near the surface of the conductor and decreases exponentially with greater depths in the conductor. Skin effect may be increased with aluminum metal lines because they are etched as opposed to a damascene process used in copper metal line interposers. FIG. 7B shows a cross-sectional end view of a typical copper metal line for connecting chips, wherein the cross-section is a square or rectangle and is about Y units (may be about 7 μm) thick in a vertical direction. As shown in FIG. 7A, the aluminum metal line cross-section is a non-rectangular shape, a cross-section of the aluminum metal line perpendicular to a plane defined by a surface of the silicon substrate 210 is anon-rectangular shape. In the present non-limiting example, the aluminum metal line cross-section is a stack of two generally trapezoidal shapes where the sides are sloped about 85 degrees from a horizontal plane. The sloped sides of the trapezoidal shapes may provide more volume at the sloped sides for improved skin effect. Further, respective metal lines 742 having lower portions 742A and upper portions 742B separated by a barrier layer 732 may provide improved skin effect because there is additional “skin” at the barrier layer 732 with aluminum metal lines shown in FIG. 7A compared to the copper metal line shown in FIG. 7B. In the examples shown in FIGS. 7A and 7B where X and Y are about 7 μm, the perimeter of the aluminum metal line cross-section (FIG. 7A) is about 23.47 μm as compared with the perimeter of the copper metal line cross-section (FIG. 7B) which is about 18 μm. Thus, the aluminum metal line cross-section perimeter is about 23% larger than a copper metal line cross-section perimeter, which may enable greater transmission of alternating electric current because the larger current density near the surface has more cross-section at a surface for transmission.

Referring to FIG. 7A, a metal line 742 may have a pad 780 thereon, wherein the pad 780 may directly accept attachment of solder balls from a chip. The pad 780 may be tungsten (W).

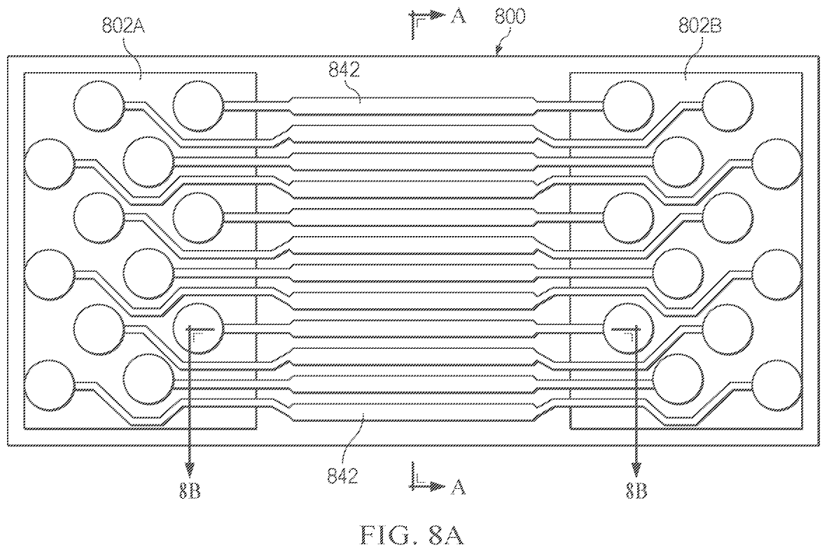

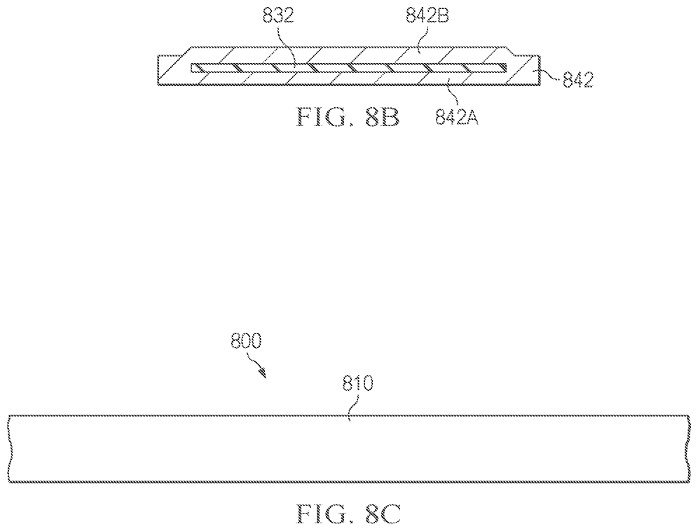

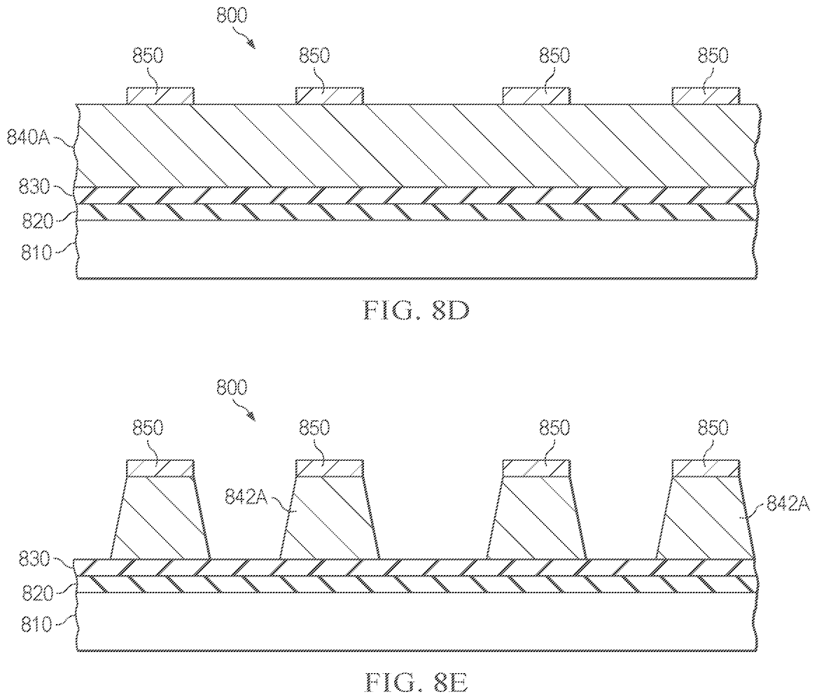

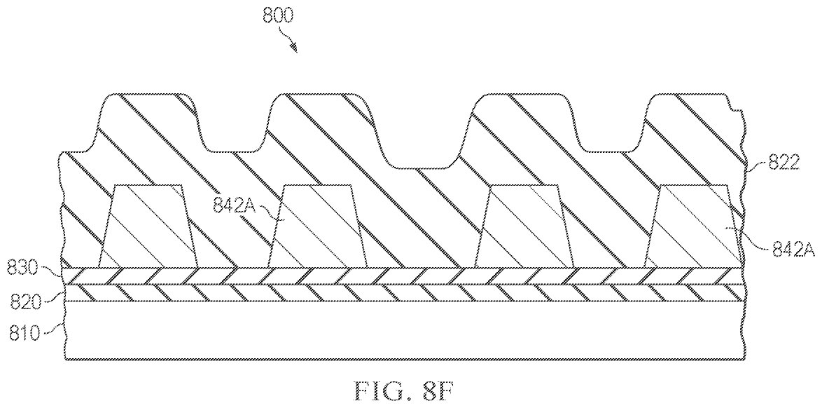

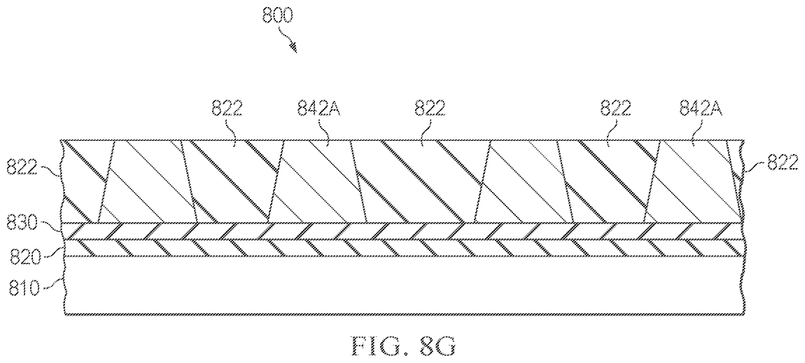

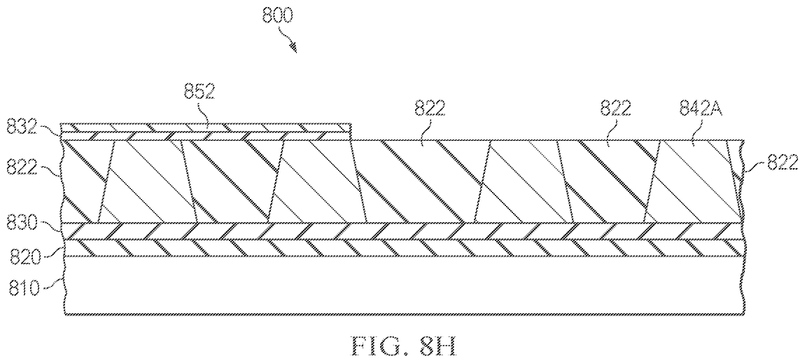

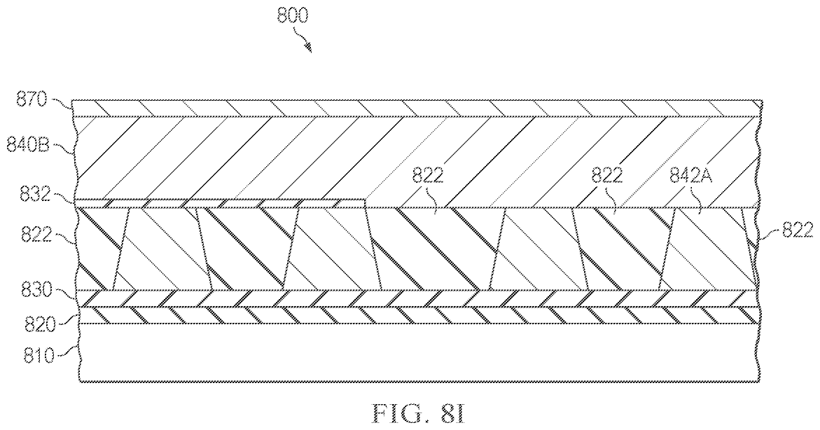

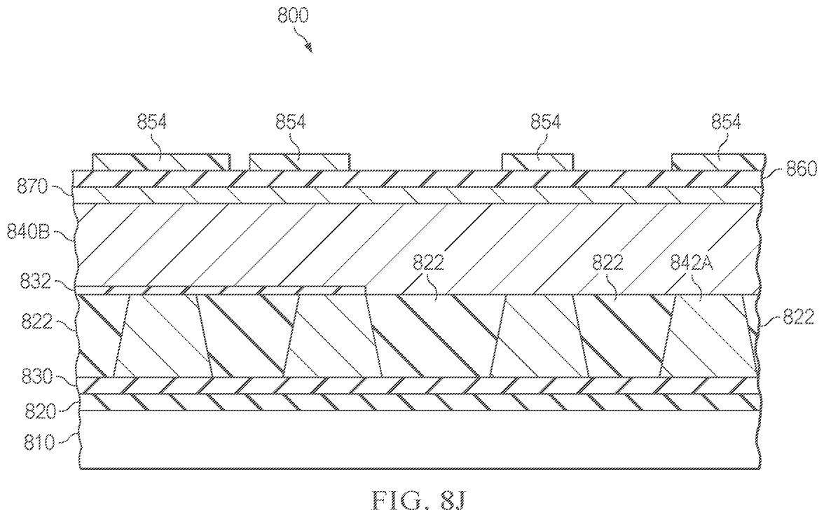

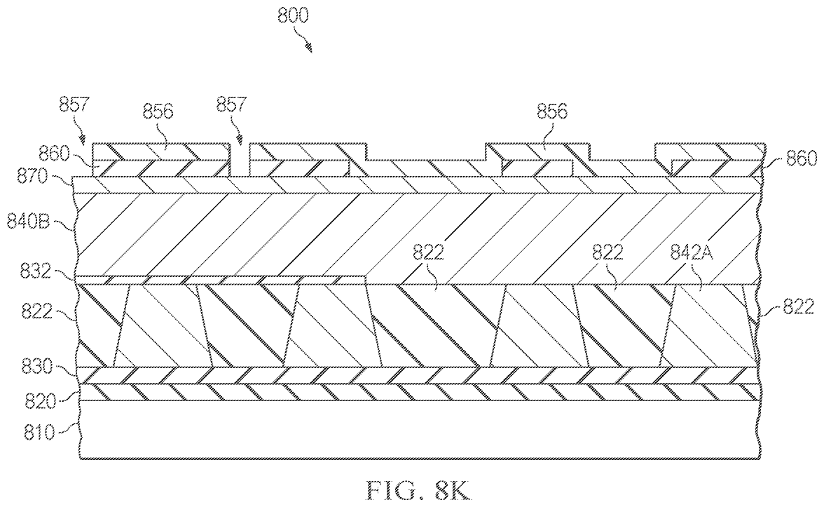

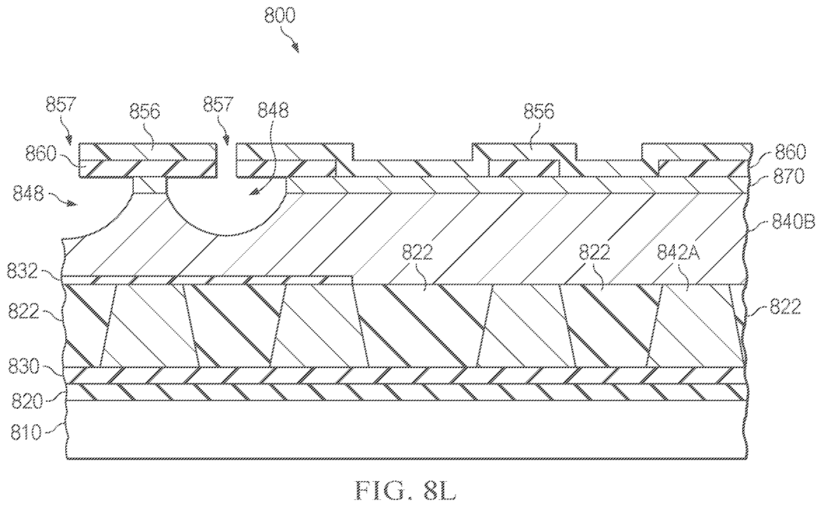

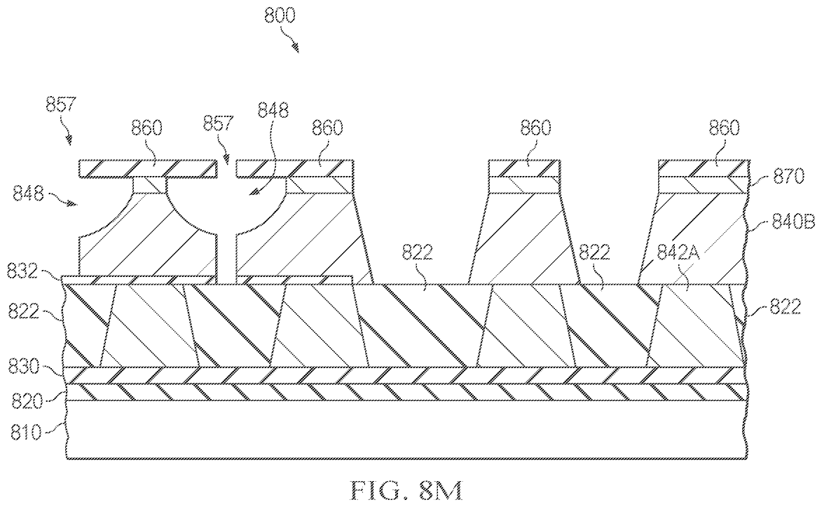

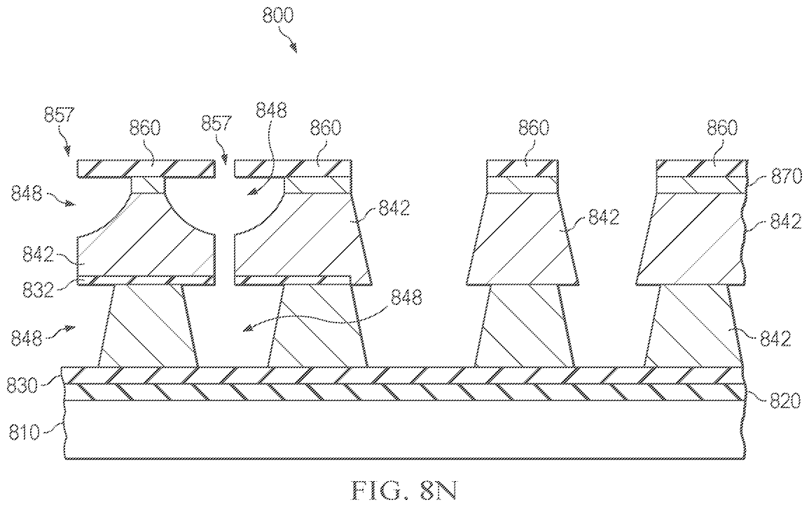

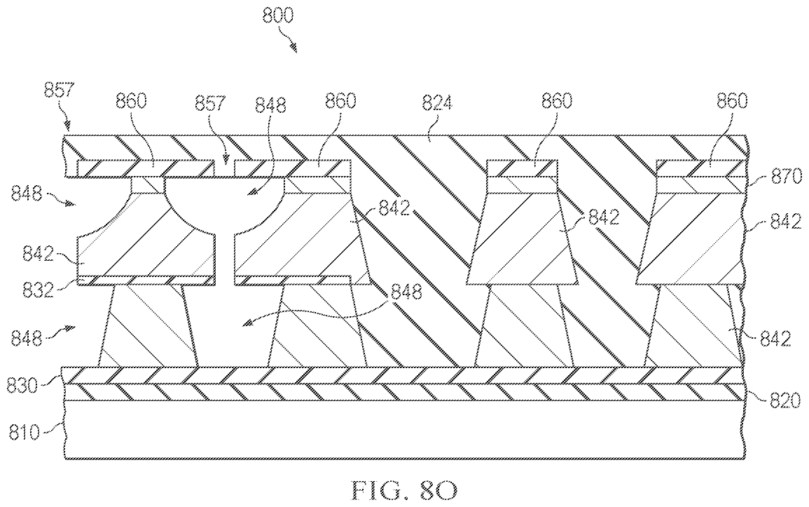

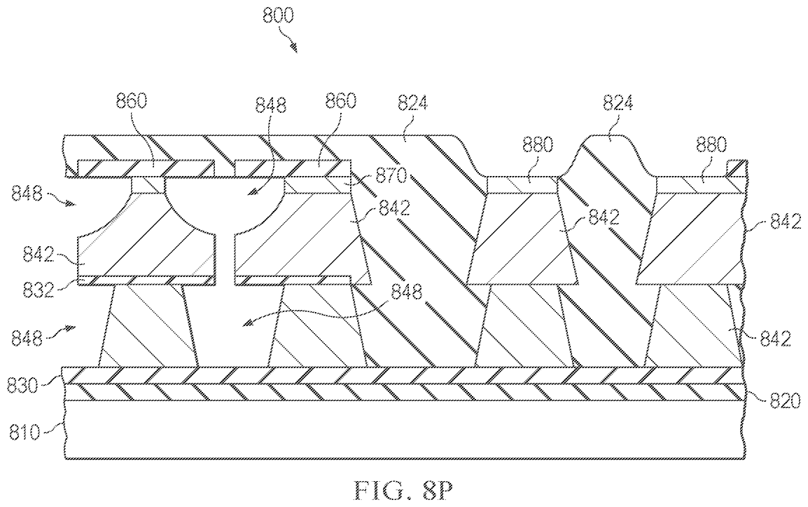

FIG. 8A shows a top view of a first chip die 802A and a second chip die 802B on an interposer 800, wherein the first and second chip dies 802A, 802B are connected by metal lines 842 that span a bridge area between the first and second chip dies.

FIG. 8B shows an enlarged cross-sectional, side view of a metal line 842 is shown taken at cross-section B-B of FIG. 8A. The metal line 842 has a lower portion 842A and an upper portion 842B separated by a barrier layer 832. The metal line 842 may be aluminum and the barrier layer 832 may be a dielectric, such as a nitride.

FIG. 8C shows a cross-sectional end view of the interposer 500 being built, which corresponds to the interposer 800 shown in FIG. 8A. The interposer building process starts with a silicon substrate 810.

FIG. 8D shows a cross-sectional end view of the interposer 800 being built as shown in FIG. 8C. A substrate insulation layer 820, which may comprise SiO₂, is deposited or grown on the silicon substrate 810. A substrate barrier layer 830, which may comprise a nitride, is deposited on the substrate insulation layer 820. A first portion of metal layer 840A, which may be aluminum, is deposited on the substrate barrier layer 830. A first photoresist layer 850 is deposited on the first portion of metal layer 840A and patterned. Alternatively, the first portion of metal layer 840A may be deposited directly on the silicon substrate 810 so as to be supported directly by the silicon substrate 810. As shown in FIG. 8D, the first portion of the metal layer 840A is indirectly supported by the silicon substrate 810 because the substrate insulation layer 820 and the substrate barrier layer 830 are between the silicon substrate 810 and the first portion of the metal layer 840A.

FIG. 8E shows a cross-sectional end view of the interposer 800 being built as shown in FIG. 8D. The first portion of metal layer 840A is dry etched through the first patterned photoresist layer 850 to the substrate barrier layer 830, whereby lower portions of metal lines 842A are formed having cross-sections perpendicular to the upper surface of the silicon substrate 810 that are trapezoidal shaped.

FIG. 8F shows a cross-sectional end view of the interposer 800 being built as shown in FIG. 8E. The first photoresist layer 850 (see FIG. 8E) is stripped and a first insulation layer 822, which may comprise SiO₂, is deposited or grown over the lower portions of metal lines 842A and the substrate barrier layer 830.

FIG. 8G shows a cross-sectional end view of the interposer 800 being built as shown in FIG. 8F. The lower portions of metal lines 842A and the first insulation layer 822 of the interposer 800 are planarized.

FIG. 8H shows a cross-sectional end view of the interposer 800 being built as shown in FIG. 8G. A first barrier layer 832, which may comprise a nitride, is deposited over the planarized lower portions of metal lines 842A and the first insulation layer 822. A barrier photoresist layer 852 is deposited over the first barrier layer 832 and patterned. The first barrier layer 832 is etched through the patterned barrier photoresist layer 852 to remove portions of the first barrier layer 832 not protected by the barrier photoresist layer 852.

FIG. 8I shows a cross-sectional end view of the interposer 800 being built as shown in FIG. 8H. A second portion of metal layer 840B is deposited over the remaining first barrier layer 832, the planarized lower portions of metal lines 842A, and the planarized first insulation layer 822. A tin (Sn) layer 870 is deposited over the second portion of metal layer 840B. The tin (Sn) layer 870 may either be deposited directly on top of the second portion of metal layer 840B or a nickel (Ni) layer may first be deposited on the second portion of metal layer 840B and the ti888n (Sn) layer 870 may then be deposited on the nickel (Ni) layer.

FIG. 8J shows a cross-sectional end view of the interposer 800 being built as shown in FIG. 8I. A hardmask 860 is deposited on the tin (Sn) layer 870. A second photoresist layer 854 is deposited over the hardmask 860 and patterned similar to the pattern for the metal lines 842 and also patterned to make sub gaps 857 (see FIG. 8K) in the region where the first barrier layer 832 was deposited, which sub gaps 857 are to make air gaps. The hardmask 860 is etched through the patterned second photoresist layer 854. The second photoresist layer 854 is subsequently stripped.

FIG. 8K shows a cross-sectional end view of the interposer 800 being built as shown in FIG. 8J. A third photoresist layer 856 is deposited on the remaining portion of hardmask 860 and on the tin (Sn) layer 870, and is patterned to provide sub gaps 857 to make air gaps.

FIG. 8L shows a cross-sectional end view of the interposer 800 being built as shown in FIG. 8K. The second portion of metal layer 840B is wet etched through the patterned third photoresist layer 856 and the remaining portions of hardmask 860 to form air gaps 848 in the tin (Sn) layer 870 and the second portion of metal layer 840B. The air gaps 848 are in the region where the first barrier layer 832 was deposited.

FIG. 8M shows a cross-sectional end view of the interposer 800 being built as shown in FIG. 8L. The third photoresist layer 856 (see FIG. 8L) is stripped. The second portion of metal layer 840B (see FIG. 8L) is dry etched through the remaining portions of hardmask 860 to remove unprotected portions of the tin (Sn) layer 870 and the second portion of metal layer 840B (see FIG. 8L) down to the first insulation layer 822. The dry etching through the sub gaps 857 in the hardmask 860 removes a portion of the second portion of metal layer 840B and a portion of the first barrier layer 832 down to the first insulation layer 822, wherein the removed portions have sizes similar to the sub gaps 857. The remaining portions of the second portion of metal layer 840B form upper portions of metal lines 842B, which are connected to lower portions of metal lines 842A to form double-stack metal lines 842. For some of the metal lines 842, the upper portion 842B is connected directly to the lower portion 842A. For other metal lines 842, the upper portion 842B is connected indirectly to the lower portion 842A through the first barrier layer 832. For metal lines 842 with a first barrier layer 832, the second portion of the metal line 842B is opposite the first portion of the metal line 842A across the first barrier layer 832, as shown in FIG. 8M.

FIG. 8N shows a cross-sectional end view of the interposer 800 being built as shown in FIG. 8M. A wet etch process is performed to remove what remains of the first insulation layer 822 (compare FIGS. 8N and 8M). In particular, the remaining portions of the first insulation layer 822 are removed in the region where the first barrier layer 832 was deposited. Air gaps 848 are formed between adjacent metal lines 842 at the sub gap 857.

FIG. 8O shows a cross-sectional end view of the interposer 800 being built as shown in FIG. 8N. A second insulation layer 824, which may comprise SiO₂, is deposited on the remaining portions of hardmask 860, the double-stack metal lines 842, and the substrate barrier layer 830. However, the sub gaps 857 in the hardmask 860 at the air gaps 848 are too small for the oxide (SiO₂) to fill the air gaps 848. The second insulation layer 824 is subsequently planarized.

FIG. 8P shows a cross-sectional end view of the interposer 800 being built as shown in FIG. 8O. The second insulation layer 824 is wet etched through a patterned fourth photoresist layer (not shown) to expose certain portions of the tin (Sn) layer 870 through the second insulation layer 824, wherein the exposed portions of the tin (Sn) layer 870 form pads 880 on the metal lines 842.

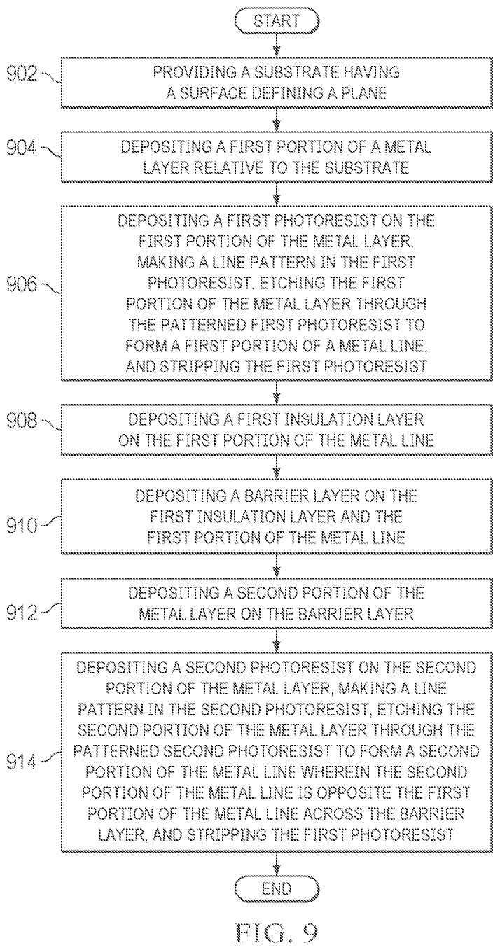

FIG. 9 shows a flow chart of a method for building an interposer. The method starts and provides 902 a substrate having a surface defining a plane. A first portion of a metal layer is deposited 904 relative to the substrate. A first photoresist layer is deposited 906 on the first portion of the metal layer, a line pattern is made in the first photoresist layer, the first portion of the metal layer is etched through the patterned first photoresist layer to form a first portion of a metal line, and the first photoresist layer is stripped. An insulation layer is deposited 908 on the first portion of the metal line. A barrier layer is deposited 910 on the first insulation layer and the first portion of the metal line. A second portion of the metal layer is deposited 912 on the barrier layer. A second photoresist layer is deposited 914 on the second portion of the metal layer, a line pattern is made in the second photoresist layer, the second portion of the metal layer is etched through the patterned second photoresist layer to form a second portion of the metal line wherein the second portion is opposite the first portion across the barrier layer, and the second photoresist layer is stripped.

Although examples have been described above, other variations and examples may be made from this disclosure without departing from the spirit and scope of these disclosed examples.

1. A method for building an interposer, the method comprising:
providing a substrate having a surface defining a plane;
depositing a first portion of a metal layer relative to the substrate;
depositing a first photoresist layer on the first portion of the metal layer, making a line pattern in the first photoresist layer, etching the first portion of the metal layer through the patterned first photoresist layer to form a first portion of a metal line, and stripping the first photoresist layer;
depositing a first insulation layer on the first portion of the metal line;
depositing a barrier layer on the first insulation layer and the first portion of the metal line;
depositing a second portion of the metal layer on the barrier layer;
depositing a second photoresist layer on the second portion of the metal layer, making a line pattern in the second photoresist layer, etching the second portion of the metal layer through the patterned second photoresist layer to form a second portion of the metal line wherein the second portion of the metal line is opposite the first portion of the metal line across the barrier layer, and stripping the second photoresist layer.

2. The method as claimed in claim 1, wherein etching the first portion of the metal layer and etching the second portion of the metal layer comprises dry etching to form first and second portions of the metal line having first and second cross-sections, respectively, perpendicular to the plane that are non-rectangular shapes.

3. The method as claimed in claim 2, wherein the first and second cross-sections respectively comprise a trapezoidal shape.

4. The method as claimed in claim 1, comprising: depositing a pad on the metal line.

5. The method as claimed in claim 1, comprising:
depositing a hardmask on the second portion of the metal layer;
depositing the second photoresist layer on the hardmask, patterning the second photoresist layer to correspond to the pattern of the lower portions of the metal line and to provide a sub gap to form an air gap, etching the hardmask, and removing the second photoresist layer;
depositing a third photoresist layer on the hardmask and the second metal layer, patterning the third photoresist layer to correspond to the sub gap to form the airgap, etching the second metal layer to form a portion of the air gap, and removing the third photoresist layer;
etching the second portion of the metal layer through the hardmask to the first insulation layer, wherein upper portions of the metal line are formed and another portion of the air gap is formed; and
etching the first insulation layer through the hardmask, wherein the remaining portion of the air gap is formed.

6. The method as claimed in claim 5, comprising:
depositing or growing a third insulation layer on the metal line without depositing or growing the third insulation layer in the air gap.

7. The method as claimed in claim 1, wherein the first insulation layer comprises oxide, wherein the first barrier layer comprises nitride, and wherein the metal line comprises aluminum.

8. An interposer device comprising:
a substrate having a surface defining a plane;
a first portion of a metal line directly or indirectly supported by the substrate;
a barrier layer on the first portion of the metal line;
a second portion of the metal line on the first barrier layer, wherein the second portion is opposite the first portion across the barrier layer.

9. The interposer device as claimed in claim 8, wherein the metal line comprises aluminum.

10. The interposer device as claimed in claim 8 wherein a first cross-section of the first portion of the metal line and a second portion of the second portion of the metal line are perpendicular to the plane and comprise a trapezoidal shape.

11. The interposer device as claimed in claim 8, comprising an insulation layer on the first portion of the metal line, wherein the insulation layer comprises oxide.

12. The interposer device as claimed in claim 8, comprising:
an insulation layer on the substrate between the substrate and the first portion of the wire line; and
a first barrier layer on the insulation layer between the substrate and the first portion of the wire line,
wherein the first portion of the wire line is on the first barrier layer, and
wherein the barrier layer on the first portion of the metal line is a second barrier layer.

13. The interposer device as claimed in claim 8, wherein a first cross-section of the first portion of the metal line and a second portion of the second portion of the metal line are perpendicular to the plane and comprise a non-rectangular shape.

14. The interposer device as claimed in claim 8, comprising an airgap adjacent the metal line.

15. The interposer device as claimed in claim 8, comprising a pad on the metal line, wherein the pad comprises tin.

16. The interposer device as claimed in claim 8, wherein the barrier layer comprises nitride.

17. A system comprising:
a first die;
a second die; and
an interposer comprising:
a substrate having a surface defining a plane;
a first portion of a metal line directly or indirectly supported by the substrate;
a portion of a barrier layer on the first portion of the metal line;
a second portion of the metal line on the portion of the barrier layer, wherein the second portion of the metal line is opposite the first portion of the metal line across the portion of the barrier layer,
a first die pad in electrical communication with the metal line, and
a second die pad in electrical communication with the metal line,
wherein the first die is in electrical communication with the first die pad and the second die is in electrical communication with the second die pad.

18. The system as claimed in claim 17, wherein a first cross-section of the first portion of the metal line and a second portion of the second portion of the metal line are perpendicular to the plane and comprise a non-rectangular shape.

19. The interposer device as claimed in claim 17, comprising:
an airgap adjacent to the metal line.

20. The system as claimed in claim 17, comprising an insulation layer on the metal line, wherein the insulation layer comprises oxide, wherein the barrier layer comprises nitride, and wherein the metal line comprises aluminum.
